(19) United States
(12) Patent Application Publication
(10) Pub. No.: US 2014/0224434 A1
(43) Pub. Date: Aug. 14, 2014

(54) MOTORIZED ROLLER SHADE WITH PHOTOVOLTAIC SHADE MATERIAL

(71) Applicants: Andrew Gross, Hoboken, NJ (US); Charles Derk, Park Ridge, NJ (US)

(72) Inventors: Andrew Gross, Hoboken, NJ (US); Charles Derk, Park Ridge, NJ (US)

(73) Assignee: Crestron Electronics, Inc., Rockleigh, NJ (US)

(21) Appl. No.: 14/178,595

(22) Filed: Feb. 12, 2014

Related U.S. Application Data
(60) Provisional application No. 61/764,809, filed on Feb. 14, 2013.

(51) Int. Cl. E06B 9/42; H02S 30/20

(52) U.S. Cl. CPC E06B 9/42; H01L 31/045
USPC 160/127; 160/405

(57) ABSTRACT

Presented is a motorized roller shade that includes a flexible shade material, a rotatably supported roller tube that windingly receives the flexible shade material, one or more flexible photovoltaic cells disposed on the flexible shade material, and a motor operably engaging the roller tube to rotate the roller tube to move the flexible shade material, where the motor receives power from the one or more flexible photovoltaic cells.

### BACKGROUND OF THE INVENTION

1. Technical Field

The present invention relates generally to roller shades, and more particularly to a motorized roller shade having photovoltaic shade material.

2. Background

Currently, to power the motor of a motorized roller shade, the motor must be electrically connected to AC or DC power or to one or more batteries. Connecting one or more motorized shades to AC or DC power either requires each shade motor's AC or DC adapter being plugged into a nearby outlet or having AC wires routed through walls to each shade motor. Powering a shade motor with one or more batteries requires having to replace or recharge those batteries when the batteries cease to provide power.

### SUMMARY OF THE INVENTION

It is to be understood that both the general and detailed descriptions that follow are exemplary and explanatory only and are not restrictive of the invention.

### DISCLOSURE OF THE INVENTION

In one aspect, the invention involves a roller shade. The roller shade include a flexible shade material, a roller tube configured to windingly receive the flexible shade material, and one or more flexible photovoltaic cells disposed on the flexible shade material.

In one embodiment, the one or more flexible photovoltaic cells are printed directly on the flexible shade material. In another embodiment, the one or more flexible photovoltaic cells are printed onto a flexible substrate and the flexible substrate is attached to the flexible shade material.

In another aspect, the invention involves a method of providing power to a roller shade motor. The method includes providing a flexible shade material, providing a rotatably supported roller tube that windingly receives the flexible shade material, disposing one or more flexible photovoltaic cells on the flexible shade material, providing a motor that operably engages the roller tube to rotate the roller tube to move the flexible shade material, establishing electrical communication between the motor and the one or more flexible photovoltaic cells, and exposing the one or more flexible photovoltaic cells to sunlight to generate electricity that powers the motor when the flexible shade material needs to be moved.

In one embodiment, disposing the one or more flexible photovoltaic cells on the flexible shade material comprises printing the one or more flexible photovoltaic cells directly on the flexible shade material. In another embodiment, disposing the one or more flexible photovoltaic cells on the flexible shade material comprises printing the one or more flexible photovoltaic cells onto a flexible material and attaching the flexible material to the flexible shade material. In still another embodiment, the method further includes exposing the one or more flexible photovoltaic cells to sunlight to generate electricity that recharges one or more batteries when the flexible shade material does not need to be moved.

In still another aspect, the invention involves a motorized roller shade. The motorized roller shade includes a flexible shade material, a rotatably supported roller tube windingly receiving the flexible shade material, one or more flexible photovoltaic cells disposed on the flexible shade material, and a motor operably engaging the roller tube to rotate the roller tube to move the flexible shade material, where the motor receives power from the one or more flexible photovoltaic cells.

In one embodiment, the one or more flexible photovoltaic cells are printed directly on the flexible shade material. In another embodiment, the one or more flexible photovoltaic cells are printed onto a flexible material and the flexible material is attached to the flexible shade material. In still another embodiment, the motorized roller shade further includes a charge controller in electrical communication with the one or more flexible photovoltaic cells. In yet another embodiment, the motorized roller shade further includes a rechargeable battery in electrical communication with the motor and the charge controller.

In another embodiment, the charge controller directs power from the one or more photovoltaic cells to the motor or to the rechargeable battery. In still another embodiment, the one or more flexible photovoltaic cells are transparent.

In yet another embodiment, the motorized roller shade further includes a voltage sensor in electrical communication with the one or more flexible photovoltaic cells, where the voltage sensor measures voltage from the one or more flexible photovoltaic cells. In still another embodiment, the motorized roller shade further includes a processor or microcontroller in communication with the voltage sensor and the motor, where the processor or microcontroller controls the motor to move the flexible shade material in response to the voltage measured by the voltage sensor.

In another embodiment, the motor receives power from the one or more flexible photovoltaic cells only when the voltage sensor measures a voltage above a minimum threshold. In still another embodiment, the motor receives power from a rechargeable battery when the voltage sensor measures a voltage below a minimum threshold.

### BRIEF DESCRIPTION OF DRAWINGS

The accompanying figures further illustrate the present invention. Exemplary embodiments are illustrated in reference figures of the drawings. It is intended that the embodiments and figures disclosed herein are to be considered to illustrative rather than limiting.

The components in the drawings are not necessarily drawn to scale, emphasis instead being placed upon clearly illustrating the principles of the present invention. In the drawings, like reference numerals designate corresponding parts throughout the several views.

FIG. 1A is an illustrative isometric front view of a roller shade with photovoltaic cells disposed on the flexible shade material, according to one embodiment of the invention.

FIG. 1B is an illustrative isometric rear view of the roller shade of FIG. 1A.

FIG. 2 is an illustrative view of a photovoltaic panel connection wire routing path through a roller tube, according to one embodiment of the invention.

FIG. 3 is an illustrative block diagram of a roller shade motor assembly, according to one embodiment of the invention.

FIG. 4 is an illustrative flow diagram of the flow of power from the photovoltaic panel to the shade motor and battery, according to one embodiment of the invention.

FIG. 5 is an illustrative circuit diagram of a photovoltaic cell and battery powered roller shade motor, according to one embodiment of the invention.

FIG. 6 is an illustrative orthographic front view of a roller shade disposed in a window, according to one embodiment of the invention.

FIG. 7 shows illustrative plots of sun intensity and shade height vs. time, according to one embodiment of the invention.

FIG. 8 shows illustrative plots of rate of change of sun intensity and shade speed vs. time, according to one embodiment of the invention.

FIG. 9 shows illustrative plots of solar voltage and smoothing function vs. time, according to one embodiment of the invention.

FIG. 10 is an illustrative table of scaling data for three sun intensities, according to one embodiment of the invention.

FIG. 11 is an illustrative table of the improvement in accuracy before and after the scaling factors of FIG. 10 are applied.

### LIST OF REFERENCE NUMBERS FOR THE MAJOR ELEMENTS IN THE DRAWING

The following is a list of the major elements in the drawings in numerical order.

100 roller shade

102 flexible shade material

104 rolled portion

106 hembar

108 roller tube

110 linear portion

112 front side

114 rear side

116 flexible photovoltaic cell

118 photovoltaic panel

120 interconnect wire

202a wire

202b wire

204 through-hole

206 sidewall

208 bore

300 shade motor assembly

302 charge controller

304 voltage sensor

306 battery

308 shade motor

310 processor/microcontroller

402 Voltage is created by sunlight striking the photovoltaic panel

404 The voltage creates a current that flows to the charge controller

406 Does the shade need to be moved?

408 Power is delivered directly to the motor

410 Power is directed to the float charger

412 Shade finished moving?

502 Schottky diode

504 battery charging circuitry

602 window

604 windowpane

606 window frame

702 period of extended darkness

704 shade raised an open position

706 rapid increase in sun intensity

708 rapid lowering of shade

### DETAILED DESCRIPTION OF THE INVENTION

Reference will now be made to the exemplary embodiments illustrated in the drawings, and specific language will be used herein to describe the same. It will nevertheless be understood that no limitation of the scope of the invention is thereby intended. Alterations and further modifications of the inventive features illustrated herein, and additional applications of the principles of the inventions as illustrated herein, which would occur to one skilled in the relevant art and having possession of this disclosure, are to be considered within the scope of the invention.

Unless the context clearly requires otherwise, throughout the description and the claims, the words ‘comprise’, ‘comprising’, and the like are to be construed in an inclusive sense as opposed to an exclusive or exhaustive sense; that is to say, in the sense of “including, but not limited to”.

### Mode(s) for Carrying Out the Invention

The present disclosure involves combining advanced photovoltaic (PV) technology with a motorized roller shade. The motorized roller shade includes a flexible shade material. This flexible shade material incorporates flexible (i.e., bendable, rollable) photovoltaic cells into or onto the flexible shade material, thereby making the flexible shade material act as a flexible photovoltaic (i.e., solar) panel

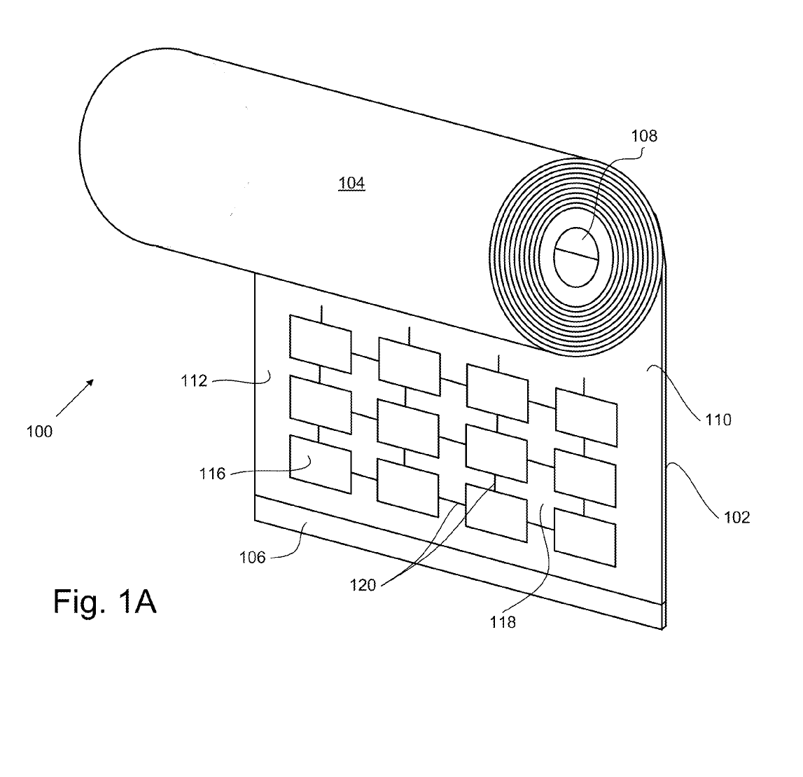

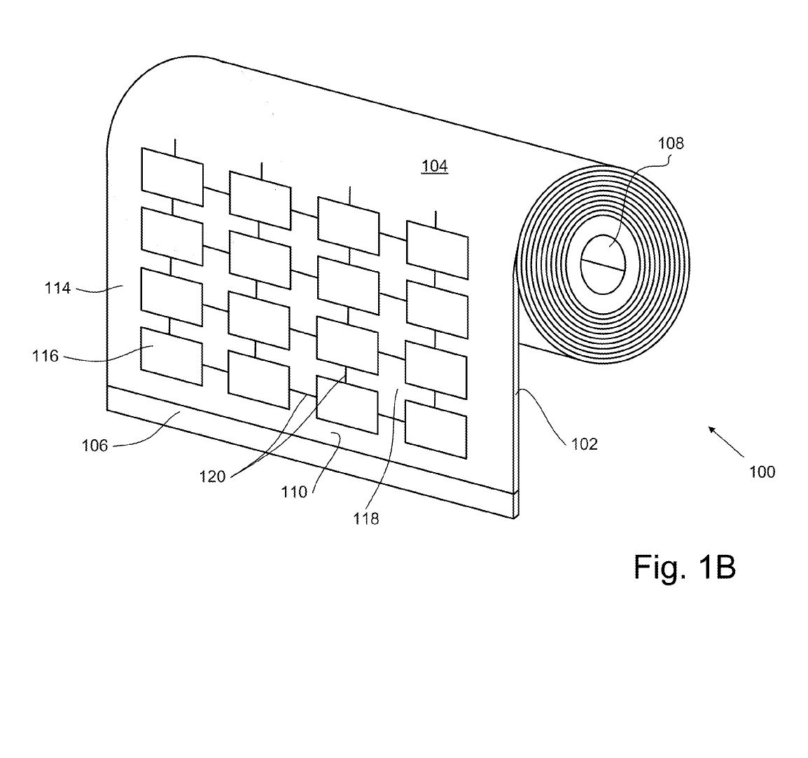

Referring to FIGS. 1A and 1B, a roller shade 100 is shown. The roller shade 100 includes a roller tube 108 and a flexible shade material 102 wound therearound creating a rolled portion 104. The roller shade 100 further includes a hembar 106 attached to the end of a linear portion 110 of the flexible shade material 102. The roller shade 100 further includes a one or more flexible photovoltaic cells 116. The one or more flexible photovoltaic cells 116 are disposed on a front side 112 and/or a rear side 114 of the flexible shade material 102, depending on the orientation of the roller shade when hung over a window. If there are two or more flexible photovoltaic cells 116 disposed on the flexible shade material 102, the two or more flexible photovoltaic cells 116 are connected to each other, either in series or in parallel, via interconnect wires 120. The one or more flexible photovoltaic cells 116 together on the flexible shade material 102 form a photovoltaic panel 118.

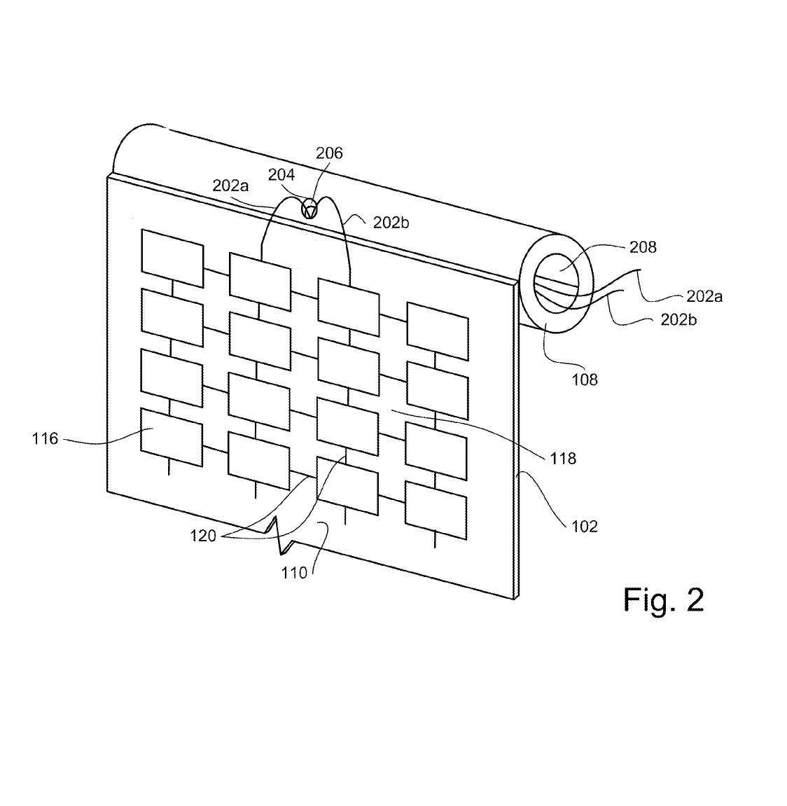

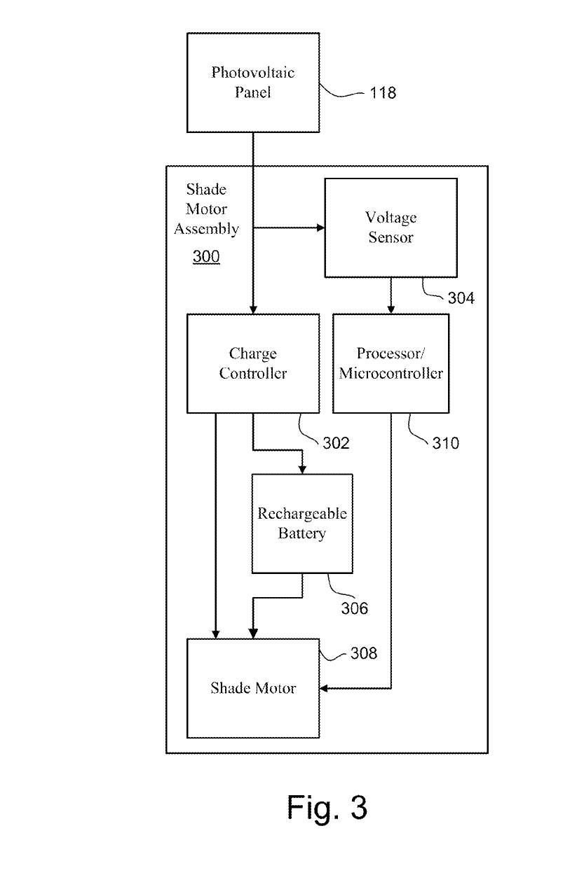

Referring to FIG. 2, wires 202a and 202b extend from the end of the flexible shade material 102 that is coupled to the roller tube 108 by methods known in the art. The wires 202a and 202b extend through a through-hole 204 in a sidewall 206 of the roller tube 108, and through the bore 208 of the roller tube 108. The wires 202a and 202b provide an electrical connection between the flexible photovoltaic cells 116 and a charge controller 302 housed in a shade motor assembly 300. In some embodiments, a voltage sensor 304 (see FIG. 3) is also housed in the shade motor assembly 300. The wires 202a and 202b are protected by the rolled portion 104 once the flexible shade material 102 is wound around the roller tube 108.

Referring to FIG. 3, in one embodiment, a block diagram of the shade motor assembly 300 is shown. The shade motor assembly 300 includes the charge controller 302, the voltage sensor 304, a processor or microcontroller 310, a rechargeable battery 306, and a shade motor 308. In various embodiments, the charge controller 302 collects the charge from the photovoltaic array 118 and charges the battery 306, which in turn, provides power to the motor 308; or the charge controller 302 supplies charge directly to the motor 308, and is discussed in further detail below. In one embodiment, the voltage sensor 304 is used to measure the voltage from the photovoltaic array 118 for the purpose of controlling the position of the roller shade 100, and is discussed in further detail below.

The flexible photovoltaic cells 116 were developed at the Massachusetts Institute of Technology. The flexible photovoltaic cells 116 (and interconnecting wires 120) are printed directly onto a substrate-independent surface (e.g., the flexible shade material 102). This printing process is accomplished by using vapors instead of liquids at temperatures less than 120 degrees Celsius. Five subsequent layers of the PV material are printed (inside a vacuum chamber) on the substrate to create an array of flexible photovoltaic cells. This process allows printing the flexible photovoltaic cells either directly onto the shade fabric, or onto a secondary flexible material that can then be attached to the flexible shade material 102 via sewing, gluing, or by other methods known in the art.

Similar flexible photovoltaic cells have been produced by Ubiquitous Energy. These flexible photovoltaic cells are also transparent and are undetectable by the human eye. These photovoltaic cells involve efficient harvesting of infrared light without affecting the visible spectrum. They utilize the excitement characteristic of small band-gap molecules that leads to oscillator bunching in order to harvest the infrared light. The small band-gap allows for greater electrical conductivity, as seen in metals, but more flexibility. In addition, the electrons can now move more freely and become elevated into the conduction band with less energy. This provides efficiencies between 21% and 35%.

In various embodiments, the charge controller 302 uses the DC output voltage of the photovoltaic panel 118 to provide the rechargeable battery 306 (e.g., either NiCd or LiFePO4) with a float-charge throughout the battery lifecycle. This allows the battery 306 to be charged at a rate similar to the rate at which it discharges. This prevents the battery 306 from being over-charged. The charge controller 302 senses when the battery 306 has a full charge and ceases all charging until the battery 306 charge falls below a specified threshold.

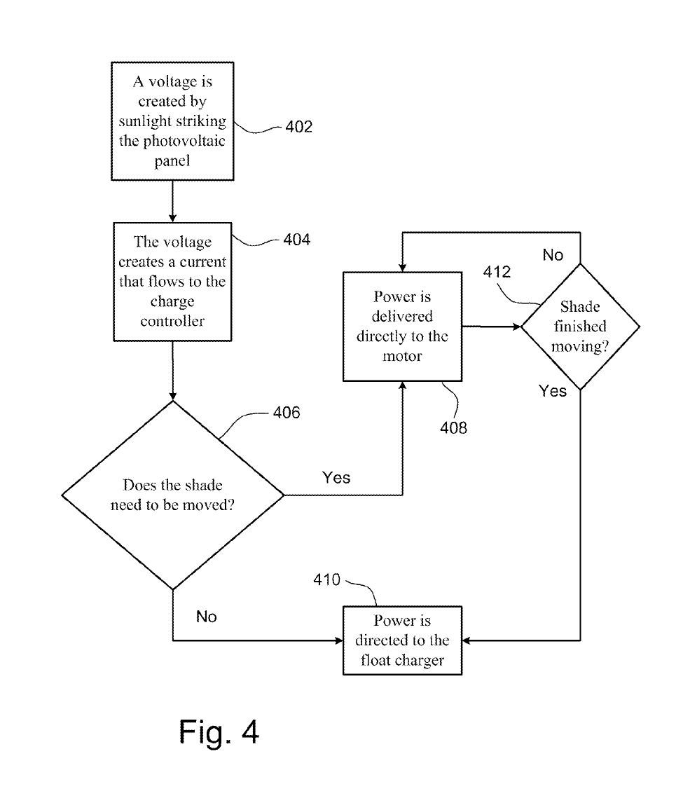

Referring to FIG. 4, a flow diagram of the flow of power from the photovoltaic panel 118 to the shade motor 308 and battery 306 is shown. First, voltage is created by sunlight striking the photovoltaic panel 118 (Step 402). Next, the voltage creates a current that flows to the charge controller 302 (Step 404). A determination is then made regarding whether the roller shade 100 needs to be moved (i.e., raised or lowered) (Step 406). If the roller shade does not need to be moved, power is directed to the charge controller 302, which determines if the battery 306 needs to be charged (Step 410). If the roller shade does need to be moved, power is delivered directly to the shade motor 308 (Step 408). Thereafter, the shade motor 308 is monitored to determine when it stops (i.e., when the roller shade 100 no longer needs to be moved) (Step 412). If the roller shade still needs to be moved, power is delivered directly to the shade motor 308 (Step 408).

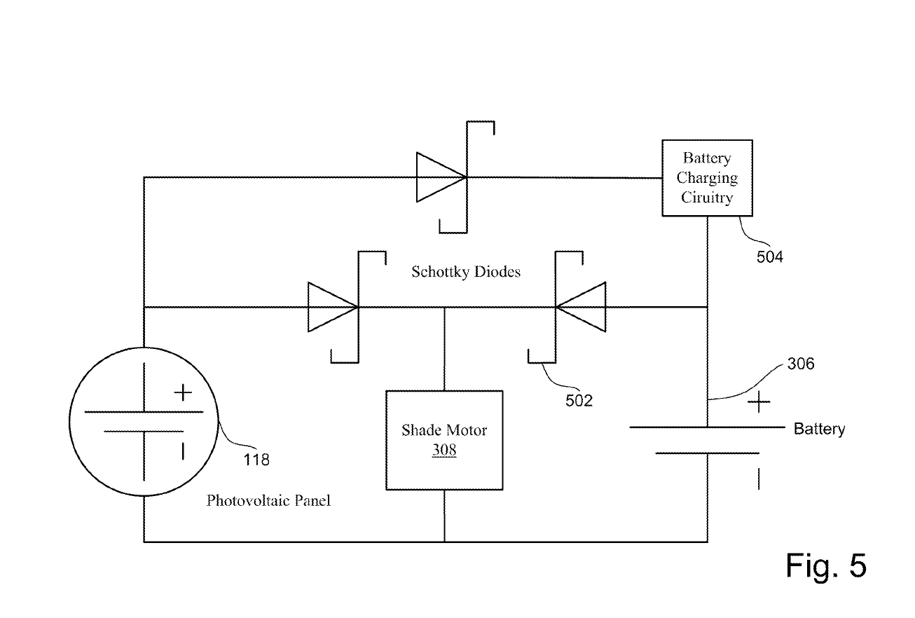

Referring to FIG. 5, in another embodiment, a circuit diagram of a photovoltaic cell and battery powered roller shade motor is shown. Schottky diodes 502 are used because of their low voltage drop and high recovery rate. The Schottky diodes 502 allow the shade motor 308 to be powered by either the photovoltaic panel 118 or the battery 306, whichever produces the larger voltage. Excess voltage from the photovoltaic panel 118 is used to charge the battery 306 via the battery charging circuitry 504 (e.g., float charger).

As mentioned above, in one embodiment, the battery 306 is disposed in the motor assembly 300. In other embodiments, the battery is disposed in, or on a top of, a housing near the shade motor to reduce wire length and visibility. In still another embodiment, the battery is disposed inside the shade roller tube.

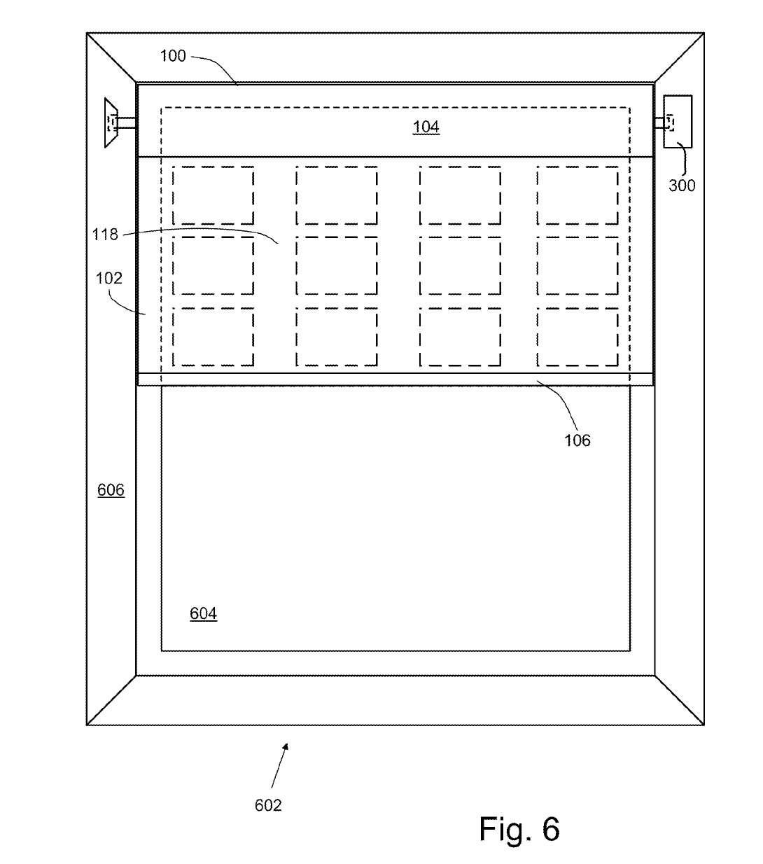

Referring to FIG. 6, roller shade 100 with motor assembly 300 mounted in a frame 606 of a window 602 is shown. As discussed above, the roller shade 100 includes flexible shade material 102 with flexible photovoltaic cells 116 disposed thereon. Specifically, the flexible photovoltaic cells 116 are disposed on the rear surface 114 of the flexible shade material 102 and facing the windowpanes 604. When the roller shade 100 is in a closed position (i.e., the flexible shade material 102 is unwound from the roller tube 108), more of the flexible photovoltaic cells receive incident sunlight. When the roller shade is in an open position (i.e., the flexible shade material is wound up around the roller tube), less of the flexible photovoltaic cells receive incident sunlight.

The disclosed motorized roller shade is more efficient and more powerful than existing roller shades, is aesthetically pleasing to the end user, and provides advanced functionality using adaptive movement. The disclosed motorized roller shade is also completely self-sufficient because no external power source (and associated wiring) is required. Consequently, the disclosed motorized roller shade causes no increase in energy usage/expense.

Specifically, the photovoltaic panel 118 (i.e., flexible shade fabric 102 with attached flexible photovoltaic cells 116) generates enough current to recharge an internal or external shade motor battery (enabling a battery lifetime of >10 years), or power the shade motor directly, depending on the amount of sunlight incident on the photovoltaic panel 118. In one embodiment, in the case of prolonged darkness (e.g., night time), in order to conserve as much battery energy as possible, the shade motor 308 receives power directly from the photovoltaic panel 118 during the day and receives power from the battery 306 only at night. If, during the day, the solar voltage does not meet or exceed a specified threshold (e.g., cloudy, rainy), then the battery 306 is used to power the shade motor 308.

Because the photovoltaic cells 116 are printed directly on the flexible shade material 102, the photovoltaic cells 116 are unobtrusive. The photovoltaic cells 116 cover the entire flexible shade material 102, which allows for a larger contact surface (as compared with conventional solar panels) for incident sunlight to power the shade motor 308 and/or charge the shade motor battery 306. Additionally, because the photovoltaic panel 118 has a large contact surface area, greater electricity production can be achieved in comparison to conventional photovoltaic cells.

Referring again to FIG. 3, in another embodiment, as mentioned above, the voltage sensor 304 is in electrical communication with the photovoltaic array 118 and is used to measure/monitor the voltage from the photovoltaic array 118. The measured voltage is proportional to the suns intensity and can be scaled and used to control the shade motor 308 to move the roller shade 100 to a specific height. The voltage sensor 304 communicates with the processor or microcontroller 310 to control the shade motor 308 to automatically move the shade in response to the intensity of the light incident on the photovoltaic array 118.

As the intensity of sun decreases, the output voltage of the photovoltaic panel 118 decreases. The voltage decrease is sensed by the voltage sensor 304. The voltage sensor 304 reports the voltage decrease to the processor or microcontroller 310, which in turn controls the shade motor 308 to raise the shade 100 based on a particular voltage threshold (i.e., sun intensity) and duration at that voltage threshold.

As the intensity of the sun increases, the voltage output of the photovoltaic panel 118 increases. The voltage increase is sensed by the voltage sensor 304. The voltage sensor 304 reports the voltage increase to the processor or microcontroller 310, which in turn controls the shade motor 308 to lower the shade 100 based on a particular voltage threshold (i.e., sun intensity) and duration at that voltage threshold.

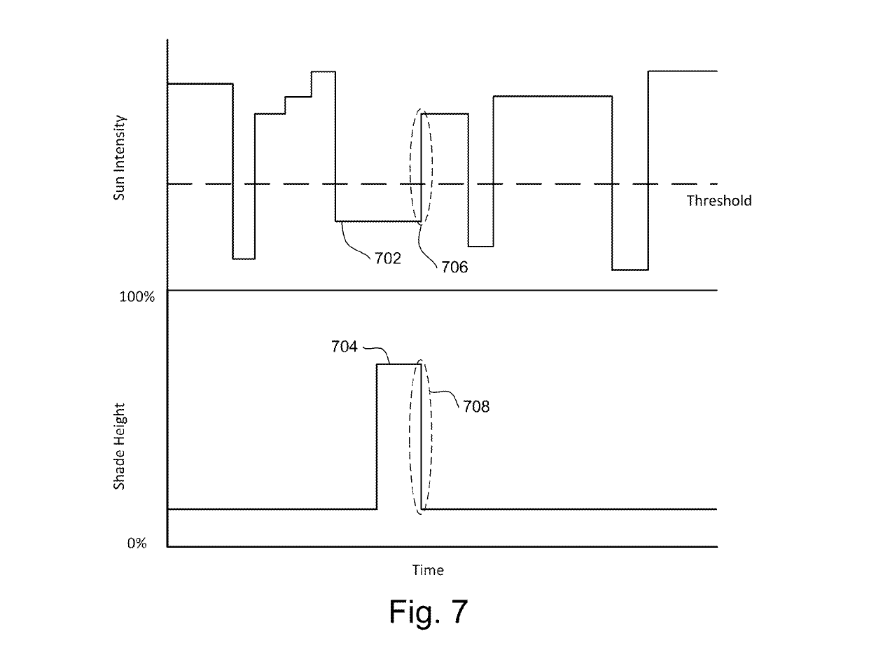

Referring to FIG. 7, example plots of sun intensity vs. time and shade height vs. time are shown. According to sun intensity vs. time plot, the sun intensity remains below a certain threshold for an extended period of time 702 (e.g., night time). The voltage sensor 304 reports this voltage to the microcontroller 310, which raises the shade 100 in response thereto 704. At some time thereafter, the sun's intensity drastically increases above the certain threshold 706 (e.g., sunrise). The voltage sensor 304 reports this drastic voltage increase to the microcontroller 310, which rapidly lowers the shade 100 in response thereto 708.

While roller shade 100 is in motion, reading of output voltage is suspended until the shade has stopped moving and can adjust itself for the new reading based on the how much of the photovoltaic panel 118 surface area is now hidden on the roller tube 108.

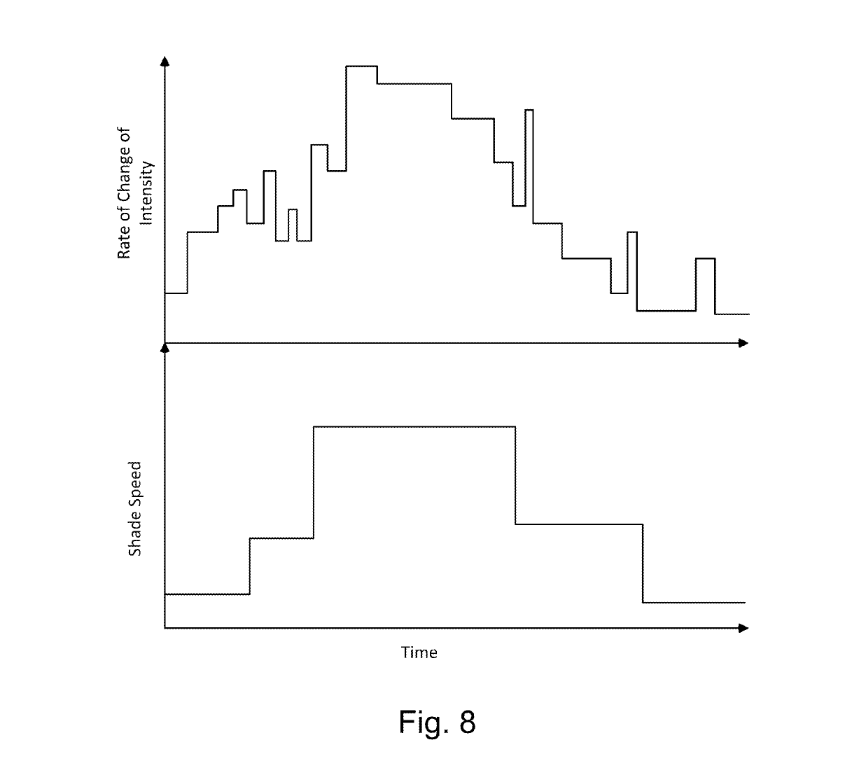

Referring to FIG. 8, plots of rate of change of sun intensity and shade speed vs. time are shown. According to the plots, it can be seen that the shade speed increases or decreases proportionally as the rate of change of sun's intensity increases or decreases.

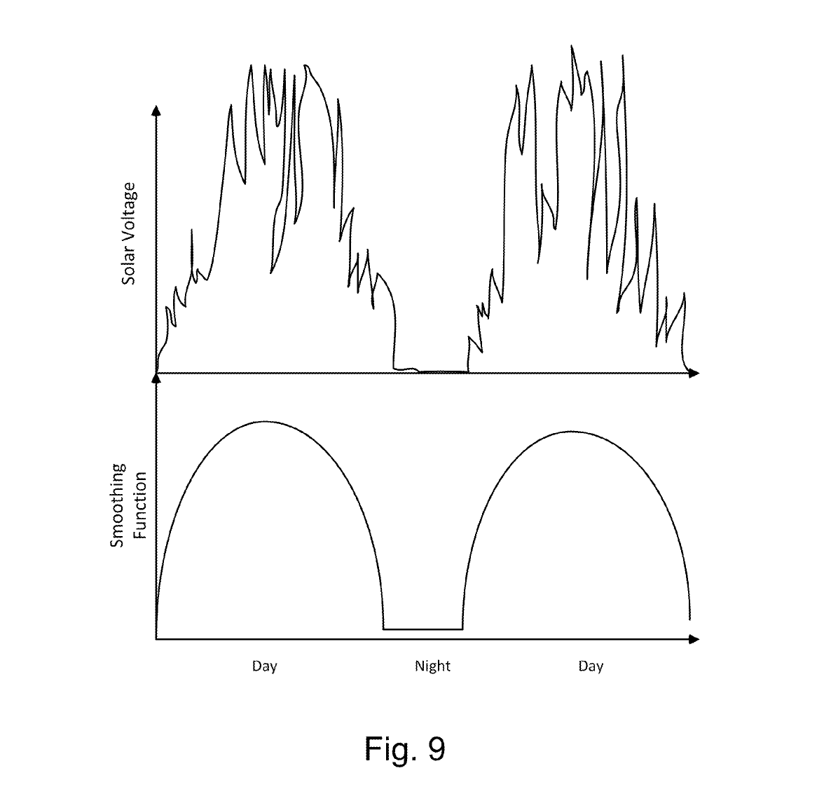

In other embodiments, the sensor/processor/microcontroller will move the shade according to sensitivity levels set by the user. In other embodiments, a smoothing function (See FIG. 9) is used to smooth out peaks and troughs in the photovoltaic cell voltage from the photovoltaic panel 118.

In still other embodiments, a manual or override mode is included for situations where the user does not want the shades to move automatically in response to sun intensity, such as when privacy is required. The user may also schedule times when to use automatic mode or manual mode.

In another embodiment, a scaling/weighting factor is used to account for differing output voltages due to dynamic shade position. This allows for a correct voltage output based upon the actual light intensity, and not the perceived voltage output dictated by the position of the shade and its photon striking area. More specifically, instances occur where the sun may be shinning extremely bright, but only a small area of a photovoltaic cell 116 receives incident photons. In this situation, the output voltage will be relatively low compared to when the full area of a photovoltaic cell 116 receives (is struck by) the same intensity of light. Additionally, if the shade is fully down, due to the increased photovoltaic cell surface area, even low intensity sunlight will still produce a relatively large voltage, which can be higher than the output voltage produced when high intensity sunlight is incident on a small area of the photovoltaic cell. This issue causes a problem with the sensor determining where to put the shade. In order to compensate for these differing output voltages so that the shade is moved to the correct position, a voltage scaling algorithm/factor is used, which takes into account the current position of the shade and the relative sun intensity.

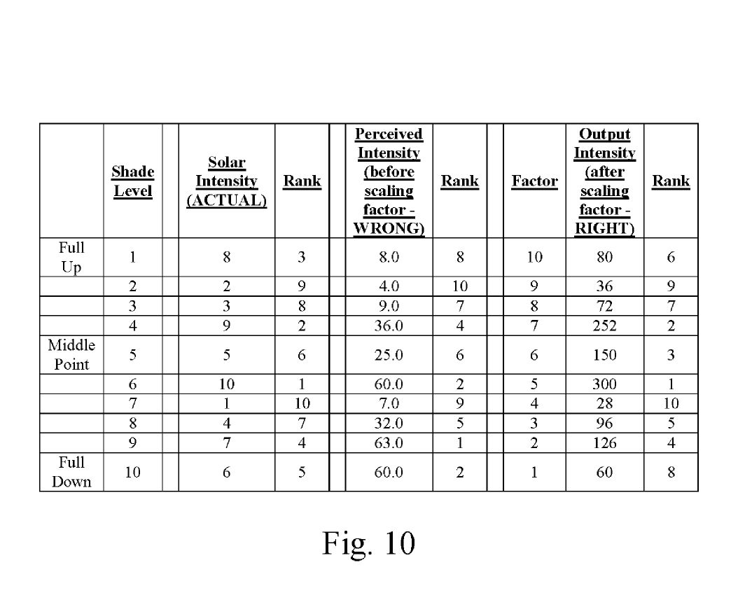

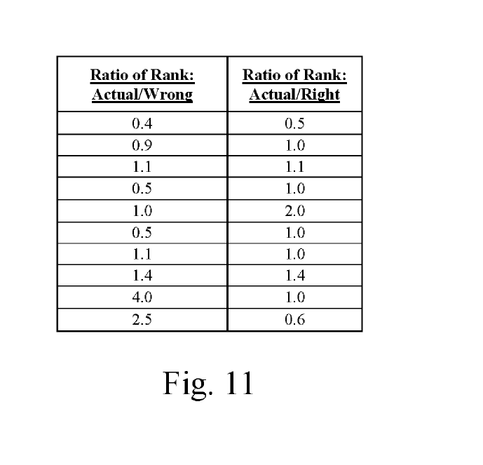

Referring to FIG. 10, an example of above-mentioned factor-based scaling implementation is shown. Three intensities are shown: the actual sun's intensity, the perceived intensity without a scaling factor, and the output intensity given by the voltage sensor after the scaling factor is implemented. Each of the intensities is ranked based upon their relative intensity descending between 1 and 10. Then, both the BEFORE and AFTER factor rankings are compared to the ACTUAL ranking. Referring to FIG. 11, a table of the improvement in accuracy (any number within 0.4 of a ratio of 1) before and after the scaling factor is applied is shown.

In other embodiments, a supplemental shade sensor is used to measure the sun's intensity when the shade is fully up (i.e., completely raised). All voltage measurements (external and shade fabric) are calibrated to mesh seamlessly.

In still another embodiment, instead of a supplemental external sensor, an optical “eye” mounted on the underside of the shade compartment is used to scan below the window to measure the intensity of sun passing through the glass. This allows for the photovoltaic panel to be completely rolled up and stored out of the way; requires no external sensor on a window or roof; and provides a more accurate depiction of the actual solar intensity passing through the window.

In another embodiment, there are three sensitivity levels used by the sun intensity sensor to dictate movement of shade. These sensitivity levels include high, medium, and low. At the high sensitivity level, the shade will move up and down parallel to the sun's intensity in a first predetermined time interval (e.g., every 1 minute). During drastic increases and decreases in the sun's intensity, the shade will move immediately. The smoothing function described above is still applied, but much more frequent shade movement is seen at this sensitivity. At the medium sensitivity level, the shade will move up and down parallel to the sun's intensity in a second predetermined time interval (e.g., every 30 minutes). During drastic increases in the sun's intensity, the shade will move down. The shade will move up only during prolonged drastic decreases in the sun's intensity. The smoothing function described above is still applied, and a normal amount of shade movement is seen at this intensity. At the low sensitivity level, the shade will move up and down parallel to the sun's intensity in a third predetermined time interval (e.g., every 1 hour). Only during drastic prolonged increases and decreases in the sun's intensity will the shade move. The smoothing function described above is still applied, but much less frequent shade movement is seen at this sensitivity. The shade is more sensitive to moving down compared to moving up. A down-only mode can be activated to only move the shade down based upon larger solar intensities.

In still another embodiment, the intensity of the sun and the percent change in the intensity of the sun is used to dictate motor speed. Depending on the sensitivity level set, the shade will move at specific intervals throughout the day. When the shade is required to move, the shade motor controller (e.g., processor, microcontroller) queries the sensor for an intensity level. This intensity level will correspond to a predetermined shade level set by the installer. If the new intensity level is 10% greater than the previous intensity level, the shade motor shall move 10% faster, and so on, up to the shade motor's maximum predetermined speed limit The percent increase in sun intensity will directly correlate to the shade motor speed. If there is a decrease in intensity, the shade motor will move at normal speed. If the percent change in the sun intensity is low, the shade will move a much slower rate. This will allow the quietest and most undetectable shade movement. All regular shade movements executed using the quietest setting on the shade motor. If the percent change in sun intensity is large, the shade motor speeds up to ensure that the high intensity sun is shining through the window for a minimal amount of time.

In yet another embodiment, since the sun's intensity and the output voltage of a photovoltaic cell are linearly related, a simple factor based system is used. The base point of the output voltage is the voltage generated when the shade is fully down. All voltages are then scaled accordingly to that value; with each specific height level assigned a specific multiplying factor.

### Alternate Embodiments

Variations, modifications, and other implementations of what is described herein may occur to those of ordinary skill in the art without departing from the spirit and scope of the invention. Accordingly, the invention is not to be defined only by the preceding illustrative description.

What is claimed is:

1. A roller shade, comprising:
a flexible shade material;
a roller tube configured to windingly receive the flexible shade material; and
one or more flexible photovoltaic cells disposed on the flexible shade material.

2. The roller shade of claim 1, wherein the one or more flexible photovoltaic cells are printed directly on the flexible shade material.

3. The roller shade of claim 1, wherein the one or more flexible photovoltaic cells are printed onto a flexible substrate and the flexible substrate is attached to the flexible shade material.

4. A method of providing power to a roller shade motor, the method comprising:
providing a flexible shade material;
providing a rotatably supported roller tube that windingly receives the flexible shade material;
disposing one or more flexible photovoltaic cells on the flexible shade material;
providing a motor that operably engages the roller tube to rotate the roller tube to move the flexible shade material;
establishing electrical communication between the motor and the one or more flexible photovoltaic cells; and
exposing the one or more flexible photovoltaic cells to sunlight to generate electricity that powers the motor when the flexible shade material needs to be moved.

5. The method of claim 4, wherein disposing the one or more flexible photovoltaic cells on the flexible shade material comprises printing the one or more flexible photovoltaic cells directly on the flexible shade material.

6. The method of claim 4, wherein disposing the one or more flexible photovoltaic cells on the flexible shade material comprises printing the one or more flexible photovoltaic cells onto a flexible material and attaching the flexible material to the flexible shade material.

7. The method of claim 4, further comprising exposing the one or more flexible photovoltaic cells to sunlight to generate electricity that recharges one or more batteries when the flexible shade material does not need to be moved.

8. A motorized roller shade, comprising:
a flexible shade material;
a rotatably supported roller tube windingly receiving the flexible shade material;
one or more flexible photovoltaic cells disposed on the flexible shade material; and
a motor operably engaging the roller tube to rotate the roller tube to move the flexible shade material, the motor receiving power from the one or more flexible photovoltaic cells.

9. The motorized roller shade of claim 8, wherein the one or more flexible photovoltaic cells are printed directly on the flexible shade material.

10. The motorized roller shade of claim 8, wherein the one or more flexible photovoltaic cells are printed onto a flexible material and the flexible material is attached to the flexible shade material.

11. The motorized roller shade of claim 8, further comprising a charge controller in electrical communication with the one or more flexible photovoltaic cells.

12. The motorized roller shade of claim 11, further comprising a rechargeable battery in electrical communication with the motor and the charge controller.

13. The motorized roller shade of claim 12, wherein the charge controller directs power from the one or more photovoltaic cells to the motor or to the rechargeable battery.

14. The motorized roller shade of claim 1, wherein the one or more flexible photovoltaic cells are transparent.

15. The motorized roller shade of claim 1, further comprising a voltage sensor in electrical communication with the one or more flexible photovoltaic cells, the voltage sensor measuring voltage from the one or more flexible photovoltaic cells.

16. The motorized roller shade of claim 15, further comprising a processor or microcontroller in communication with the voltage sensor and the motor, the processor or microcontroller controlling the motor to move the flexible shade material in response to the voltage measured by the voltage sensor.

17. The motorized roller shade of claim 15, wherein the motor receives power from the one or more flexible photovoltaic cells only when the voltage sensor measures a voltage above a minimum threshold.

18. The motorized roller shade of claim 17, wherein the motor receives power from a rechargeable battery when the voltage sensor measures a voltage below a minimum threshold.
